(19) United States
(12) Patent Application Publication
(10) Pub. No.: US 2020/0333131 A1
(43) Pub. Date: Oct. 22, 2020

(54) STRUCTURED LIGHT ILLUMINATORS INCLUDING A CHIEF RAY CORRECTOR OPTICAL ELEMENT

(71) Applicant: Princeton Optronics, Inc., Mercerville, NJ (US)

(72) Inventors: Baiming GUO, Mercerville, NJ (US); Jean-Francois SEURIN, Princeton Junction, NJ (US); Chuni GHOSH, West Windsor, NJ (US); Laurence WATKINS, Pennington, NJ (US)

(73) Assignee: Princeton Optronics, Inc., Mercerville, NJ (US)

(21) Appl. No.: 16/763,210

(22) PCT Filed: Nov. 9, 2018
(86) PCT No.: PCT/US2018/060023

§ 371 Date: May 11, 2020

Related U.S. Application Data
(60) Provisional application No. 62/587,032, filed on Nov. 16, 2017.

(51) Int. Cl. G01B 11/00; H01S 5/42; G02B 27/42; H01S 5/183; H01S 5/00; G06K 9/20; G06K 9/00

(52) U.S. Cl. CPC G01B 11/002; H01S 5/423; G02B 27/425; G06K 9/00335; H01S 5/005; G06K 9/2036; H01S 5/18388

(57) ABSTRACT

The present disclosure describes techniques to improve the resolution and reduce the distortion of structured light projection in miniature wide-angle VCSEL array projection modules used for 3D imaging and gesture recognition. The projector module includes a chief ray corrector optical element, which directs the VCSEL beams along the projector lens chief ray paths. The VCSEL structured illumination projector using the chief ray optical element corrector can create a high resolution, low distortion structured light pattern over an extended distance range greater that the projector lens image focal range. The corrector element is placed close to the VCSEL array. The corrector element can be implemented in various ways including, for example, a refractive lens, diffractive lens or microlens array, depending on the specific application requirements and optical configurations.

### FIELD OF THE DISCLOSURE

The present disclosure relates to vertical cavity surface emitting laser (VCSEL) or other illuminators operable to project a structured light pattern. In particular, the present disclosure relates to improving the resolution and reducing the distortion of miniature modules for structured light projection and three-dimensional (3D) imaging using, for example, VCSEL arrays including addressable arrays, which can generate passive and dynamic structured light patterns for 3D imaging, gesture recognition and other applications.

### BACKGROUND

Some miniature optical projection systems project an image of a VCSEL array onto a scene to form a structured illumination of the objects in the scene. The VCSEL array can be configured in various ways including regular or non-regular arrays to form the projected array of spots or others forms of images. A camera or other type of sensor is used to record the illumination image incident on the objects in the scene. This image can be analyzed, and properties of the objects such as 3D location, movement and other characteristics can be determined.

Many illumination applications require wide-angle illumination over projection angles of 110° or even larger. To achieve this illumination in a small or miniature module suitable for mobile electronic devices or similar applications, a short focal length lens typically is required. In addition, to obtain the large angle illumination with good structure resolution a VCSEL array, which has larger lateral dimensions than the lens aperture typically is required. The VCSEL array emits narrow beams perpendicular to the VCSEL array plane; thus, many of the outer beams will not pass through the lens and are blocked. The blocked beams will not be imaged onto the scene as part of the illumination pattern.

One known solution to address the foregoing issue in wide-angle projection is to place a field lens near the object plane of a lens to focus the light rays from the object through the lens aperture. This approach also can work for projecting the beams emitted by the VCSEL. In this arrangement, a converging optical element is placed near the VCSEL array to focus the beams from the VCSEL array through the lens aperture.

Wide-angle lenses, however, typically produce significant distortion in images. The distortion changes the lateral form of the image with respect to the object pattern and also affects the image resolution. When projecting images using incoherent light, the rays from the different parts of the object fill the lens aperture so that each point in the image receives light that has passed through all parts of the lens aperture. The distortion from the lens causes these rays to deviate from the ideal projection location, resulting both in image distortion and decrease in image resolution.

Light beams from the VCSEL array are relatively narrow and, thus, the beams do not fill the lens aperture. They behave similarly to single rays and the beam from each VCSEL element passes through a restricted region of the lens aperture. This result also will occur when a field lens is used to focus the beams through the lens aperture. The consequence of this arrangement is that, because of the lens distortion, the beams are projected to locations that depend on the actual optical path the beams take through the lens aperture. In addition, the beams themselves are distorted, increasing their divergence depending on where the beam propagates through the lens aperture. Because the accuracy of 3D determination depends on the accuracy of the illumination pattern structure, distortion of the pattern will result in errors.

### SUMMARY

The present disclosure describes illuminators that include a chief ray corrector optical element. For example, the disclosure describes VCSEL-based projectors that can help alleviate or overcome the VCSEL projection problems discussed above by propagating the VCSEL beams along the chief ray angles of the projection lens. As used in this disclosure, the chief ray of the lens is a ray that propagates from the object point through the optical center (i.e., entrance pupil) of the lens to the design image point. The other rays that propagate from the object point through other regions of the lens are designed to be incident on the same image point, but due to lens distortion may deviate from this location. By directing the narrow VCSEL beams along the chief ray, the beams are located at the lens design image location. In addition, because the VCSEL beams have narrow divergence, substantially the entire beam propagates close to the chief ray so that the effects of lens distortion are reduced or minimized.

In one aspect, for example, the present disclosure describes a VCSEL array structured light illuminator that includes an array of VCSELs operable to produce beams of light. The illuminator also includes a projection lens having chief ray angles, and an optical element disposed between the array of VCSELs and the projection lens. The optical element is operable to bend the beams of light produced by the VCSELs to match corresponding chief ray angles of the projection lens, which is operable to project beams of light received from the optical element to generate a structured illumination pattern.

In another aspect, the present disclosure describes an imaging apparatus that includes the VCSEL array structured light illuminator. A camera is mounted off-axis of the illuminator and is operable to record a structured illumination pattern reflected or scattered by the one or more objects. A computing device includes one or more processors and is operable to compute a respective location or movement of the one or more objects based on the recorded pattern.

According to another aspect, the present disclosure describes a method including producing light beams by an array of light emitting elements, causing the light beams to be bent by an optical element so as to match corresponding chief ray angles of a projection lens, and subsequently passing the light beams through the projection lens so as to project a structured illumination pattern onto one or more objects. In some instances, the method further includes recording a structured illumination pattern reflected or scattered by the one or more objects, analyzing the recorded pattern using a computing device to determine a respective location and/or movement of the one or more objects.

Some implementations include one or more of the following advantages. For example, 3D measurement systems typically are required to be operable to measure depth over a large distance. This distance typically is longer than the focus depth of the projection lens. However, since the VCSEL projector is propagating narrow divergence beams, the pattern resolution can be maintained over a longer distance than the focus depth of the image. Depending on where the beams propagate through the projection lens, the beams will be displaced from the chief ray until arriving at the image focal point. Because of this, the regions away from the image focus point will incur structured pattern distortion even though the beam size remains small for good pattern resolution. By propagating the beams along the chief ray angle this source of distortion can be eliminated. The pattern structure can be maintained throughout the depth over which the 3D measurements are being made.

As described in this disclosure, the chief ray optical element corrector is designed to direct the VCSEL array beams along the chief rays of the projection lens to form the high resolution low distortion structured light pattern. The corrector element can be placed close to the VCSEL array. The corrector element can take any one of several forms depending on the specific application requirements and optical configurations. In some cases, the corrector element includes a converging refractive lens. The surface may be spherical or aspherical to optically match the VCSEL array beams to the characteristics of the projection lens chief rays.

In some instances, the optical element for the chief ray corrector includes a fresnel lens. An advantage of this type of lens is that its thickness can be made smaller than a refractive lens. Alternatively, as the VCSEL output has a narrow wavelength, a diffractive lens can be used. Such a lens can provide the same small thickness benefit as the diffractive lens.

Another type of corrector optical element that can provide the same small thickness benefit is a microlens array. The microlens array can be configured to match to the VCSEL array, with the exception that the microlens position is progressively offset from the VCSEL array element location. Thus, the microlenses at the center of the VCSEL array are aligned to the VCSEL beams axes. The microlenses then are offset progressively at locations further out towards the periphery of the array. The offset microlenses bend the outer VCSEL beams towards the center of the projection lens. The offset is specifically designed with respect to the VCSEL array elements so that the beams are aligned to the chief ray angles of the projection lens.

In some cases, the microlens array can be a separate optical element which is aligned to the VCSEL array. The microlens array can also be directly fabricated onto the VCSEL array. This has many benefits including reducing the assembly cost by integrating the fabrication of the microlens with the VCSEL fabrication processes.

Other aspects, features and advantages will be readily apparent from the following detailed description, the accompanying drawings, and the claims.

### BRIEF DESCRIPTION OF THE DRAWINGS

FIG. 1 illustrates a problem that can occur in connection with some VCSEL array structured light illuminators.

FIG. 2 illustrates another problem that can occur in connection with some VCSEL array structured light illuminators.

FIG. 3 illustrates an example of a VCSEL array structured light illuminator including a refractive lens located near the VCSEL array to bend the VCSEL beam and align it with a chief ray angle.

FIG. 4 illustrates another example of a VCSEL array structured light illuminator including a diffractive lens to bend the VCSEL beam and align it with a chief ray angle of the projection lens.

FIG. 5 illustrates an example of a VCSEL array structured light illuminator including an offset microlens array to align the VCSEL beams with chief ray angles of the projection lens.

FIG. 6A is a photograph of a structured light image without the chief ray angle corrector; FIG. 6B shows an improvement realized using the chief ray angle corrector.

### DETAILED DESCRIPTION

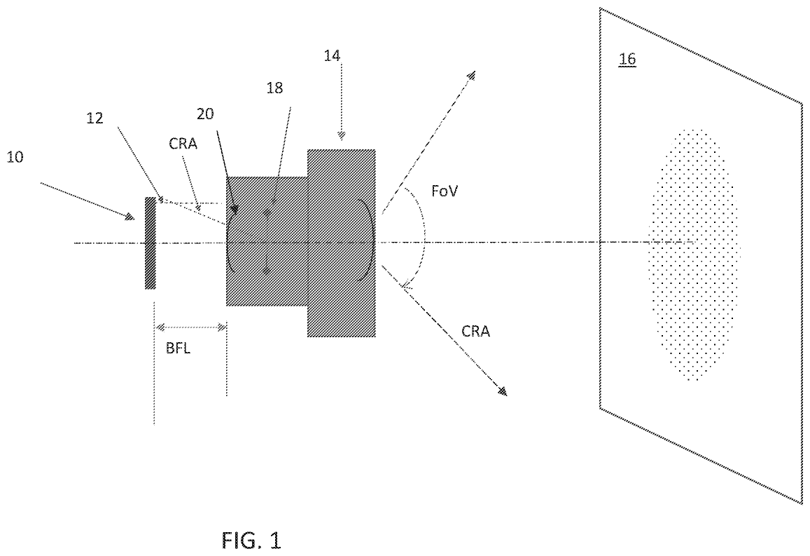

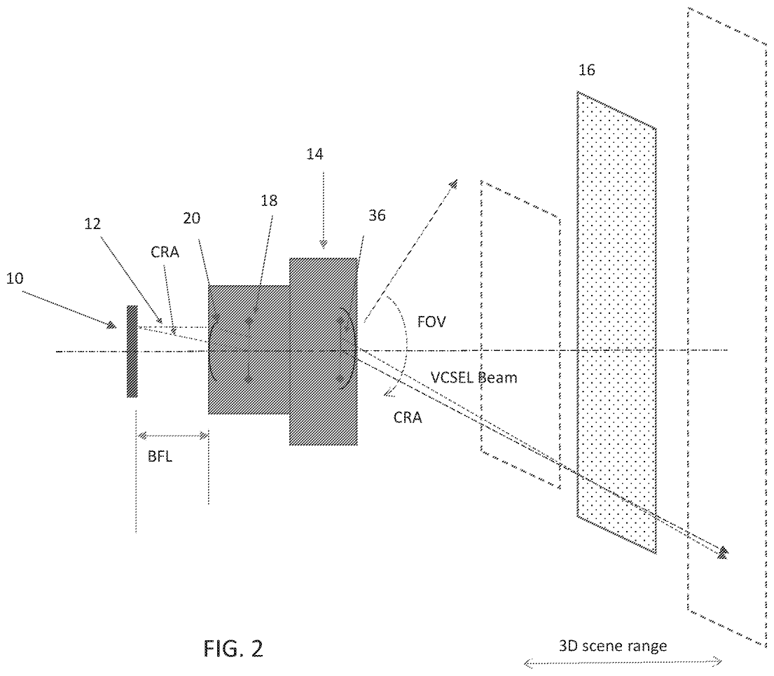

FIGS. 1 and 2 illustrate various problems that can arise when using a VCSEL array to project a 3D structured illumination pattern onto a scene. As shown in FIG. 1, a VCSEL array 10 emits a parallel array of narrow divergence beams 12 in a direction perpendicular to the VCSEL array plane. A projection lens 14 produces an image of the VCSEL array in a region of interest (e.g., on objects in a scene) and forms a structured illumination pattern 16 based on the structured form of the VCSEL array 10. As the VCSEL beams 12 have a narrow divergence, the structured image resolution is maintained over a significant distance in the region of interest. This feature can be important for 3D imaging and similar applications so that the structured image pattern 16 is maintained when incident on objects at different distances in the region of interest.

FIG. 1 also illustrates a problem that can arise when the VCSEL array 10 is larger than the projection lens aperture 18. VCSEL beams from outer parts of the VCSEL array are not captured by the input lens element 20. As a consequence, these beams are not imaged into the structured illumination region.

As further illustrated by FIG. 2, VCSEL beams generated at the inner part of the array 10 are captured by the projection lens 14 and imaged onto the structured illumination region. However, beams not in the center of the array 10 are not incident on the center of the lens 14. As a consequence, these beams travel through the outer portions of the projector lens elements at different locations from the chief ray. For a perfect (i.e., ideal) lens, this situation would not be a problem at the image focus because the lens elements would direct the VCSEL beams to the correct imaging location. In practice, however, this will not be the case, and the distortion properties of the projection lens 14 direct the beams to slightly different positions in the imaging region. The VCSEL beams are not infinitesimal diameter beams, but have a finite diameter. As a result, the lateral components of the beam will incur this distortion, which modifies the diameter and profile of the beam.

An additional problem can occur in some cases for 3D sensing applications in which the 3D scene range is longer than the image depth of focus, especially for a wide-angle projection lens. If the VCSEL beam divergence is small, the resolution of the structured image will be maintained beyond this depth of focus. However, outside the focus point, the VCSEL beam deviates from the chief ray angle (CRA). This deviation can result in distortion of the pattern structure for regions in front of, and beyond, the image focal point.

The use of a field lens can obviate the first problem by converging the VCSEL beams through the lens aperture such that none of them is blocked. However, such an approach does not address the other issues because the beams will still propagate through various parts of the lens along a non-optimum path. Because the accuracy of 3D determination depends on the accuracy of the illumination pattern structure, any distortion of the pattern structure will result in errors, for example, in 3D determination and gesture recognition applications.

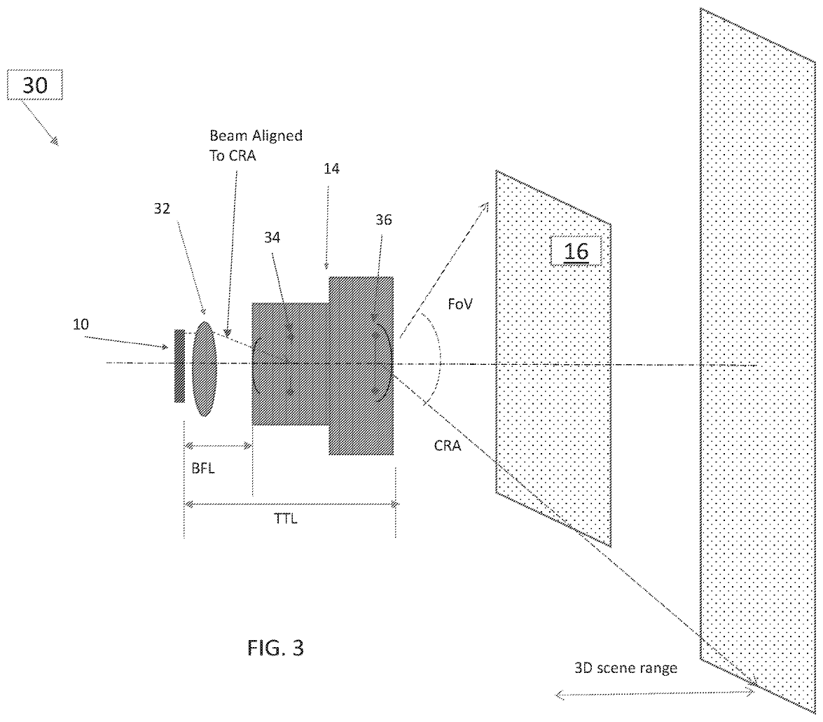

FIG. 3 illustrates an example of an arrangement of a VCSEL array structured light illuminator 30 in which a converging lens 32 is placed close to the VCSEL array 10. The converging properties of the lens 32 are designed to match the VCSEL array beam angles to the relevant chief ray angles of the projection lens 14. In FIG. 3, only one VCSEL beam and chief ray angle are shown to illustrate the principal, although in practice there will be many such beams. The lens converging properties are designed to direct all the VCSEL beams along the respective chief ray angles so that all the beams pass through the center of the effective i/p aperture 34 of the projection lens 14. The effective i/p aperture 34 also can be referred to as the entrance pupil of the projection lens 14.

The VCSEL beams are transmitted through the projection lens 14 along the chief ray angles with minimal distortion of the beams. The beams exit the projection lens 14 through the center of the exit pupil (i.e., the effective lens o/p aperture 36 viewed from the output side). The beams thus can be projected to the design location in the structured illumination region with minimum beam distortion and without deviation from the designed location in the structured image over the whole 3D scene range.

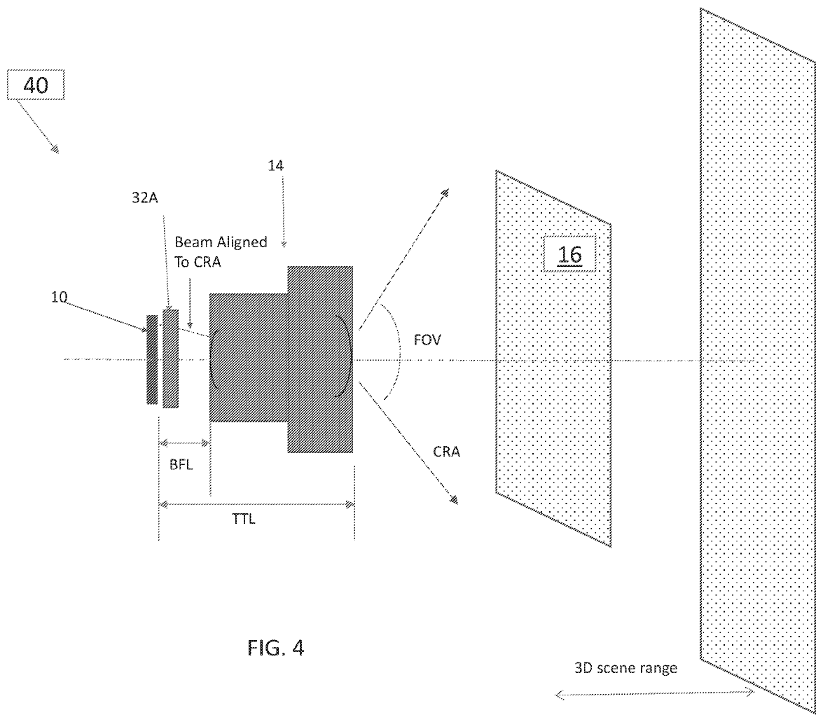

FIG. 4 illustrates another example of a VCSEL array structured light illuminator 40 that includes an alternative optical element 32A for converging the VCSEL beams through the projection lens 14 along the chief ray angles. In this case, the element is a diffractive element 32A disposed near the VCSEL array 10 and designed to diffract the VCSEL beams towards the center of the entrance pupil of the projection lens 14. The diffractive structure at the location of each VCSEL beam is designed to bend the beam to the angle that matches the chief ray angle of the projection lens 14 for that element location.

In some implementations, a Fresnel lens is used to converge the VCSEL beams for CRA matching. In such cases, instead of a diffractive structure to bend the VCSEL beam, a small prism section is used to bend the beam. Each section prism angle is designed to bend the VCSEL beam to match the chief ray angle of the projection lens. A benefit of using the diffractive optical element or the Fresnel lens is that for a given optical power, the thickness of the optical element can be much smaller than the refractive element. For applications in miniature projection modules (e.g., cell phones and tablets), this is a significant advantage.

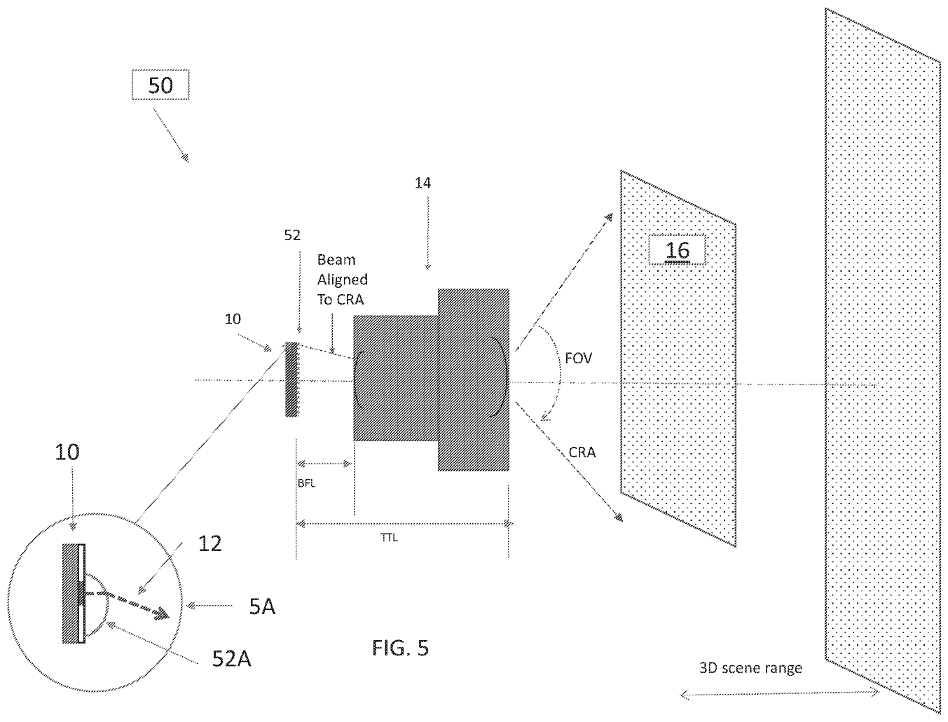

As shown in FIG. 5, in some implementations, a VCSEL array structured light illuminator 50 includes a microlens array (MLA) 52 operable to converge the beams from the VCSEL array 10 to match the CRA of the projection lens 14. The inset diagram 5A demonstrates how an offset microlens 52A bends the VCSEL beam 12 in a direction towards the offset direction. The amount of deflection is proportional to the magnitude of the offset.

The microlens array 52 can be designed with the same layout as the VCSEL array 10 structure, except that a negative radial offset is introduced. The magnitude of the offset increases for increased distance from the center of the array. The offset is designed to bend the VCSEL beam 12 to match the CRA for the projection lens 14 at that radial location. The magnitude of the deflection is a function of both the offset and the micro lens focal length.

In some instances, the microlens array is a separate optical element, which is aligned and mounted during module assembly. A more advantageous approach, in some case, is to fabricate the microlens array 52 directly on top of the VCSEL array 10. Various methods may be used to achieve the desired result, making refractive or diffractive microlens or even microprism arrays. One method uses semiconductor fabrication processes to deposit the optical refractive material on the VCSEL array 10. Etching or other molding techniques then can be used to form the spherical or aspherical lens surface profile. This approach has several benefits. For example, it can result in a very thin optical element suitable for miniature modules. Fabrication of the MLA 52 on the VCSEL array 10 can be highly compatible with the fabrication process of the VCSEL itself. Finally, the approach can eliminate costly alignment and bonding process required when using a separate MLA.

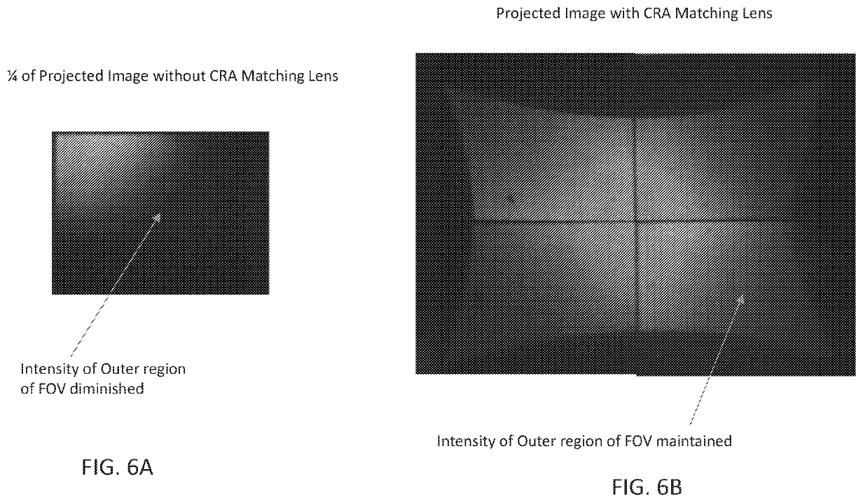

FIGS. 6A and 6B are photographs illustrating the type of significant improvement in the structured illumination that can be obtained by using a CRA matching optical element. FIG. 6(A) is ¼ of the image projected without the use of the MLA projection lens. The image in the center displays reasonable brightness. However, the outer region of the illumination pattern is dark because the VCSEL beams at this outer region are blocked by the lens aperture. FIG. 6(B) shows the full image projected using the MLA matching lens. In this image, the outer regions of the structured illumination are much brighter, and none of the VCSEL array beams is blocked by the projection lens aperture. Although the brightness of the image reduces at the outer radial locations, this is as result of the cosine effect of using a flat imaging screen. The beams at the outer locations are incident at a large angle on the screen, thus increasing the incident beam area so that the power density is lower.

Although the foregoing examples are described with respect to VCSEL arrays, other types of light emitting elements may be used in some implementations, such as other types of surface emitting semiconductor light sources that emit a narrow beam (e.g., RC-LEDs). The wavelength of light (i.e., radiation) emitted by the VCSELs or other light emitting elements may be in the infra-red (IR), near IR, far IR, visible, or other parts of the electromagnetic spectrum, depending on the application. The VCSELs or other light sources can be addressable independently, in groups (sub-groups) or collectively.

A method of 3D imaging using structured imaging is to project a known structured pattern on one or more objects in the scene of interest using, for example, any of the illuminators described above. A camera or other imaging device can be mounted off-axis and used to record the structured illumination pattern reflected or scattered by the object(s). This recorded image is a modified structured image; the nature of the modification depends on the object position and angle of the off-axis viewing by the camera. This modified image can be analyzed (e.g., by a computing device that includes one or more processors) using known techniques to compute the location and/or movement of the object(s). Since the structured image modification forms the basis for the determination of the objects' positions, any distortion of the original structured illumination pattern will introduce errors. Thus, the present disclosure represents an important development for accurate 3D imaging and gesture recognition systems.

Various aspects of the subject matter and the functional operations described in this specification (e.g., analysis and computation of the locations and/or movements of the object(s)) can be implemented in digital electronic circuitry, or in computer software, firmware, or hardware, including the structures disclosed in this specification and their structural equivalents, or in combinations of one or more of them. Embodiments of the subject matter described in this specification can be implemented as one or more computer program products, i.e., one or more modules of computer program instructions encoded on a computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The terms “data processing apparatus” and “computer” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio player, a Global Positioning System (GPS) receiver, to name just a few. Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

Aspects of the subject matter described in this specification can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described is this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

Although various details are described in the foregoing implementations, various modifications can be made. Thus, some implementations may include components in addition to those described above, whereas some implementations may omit one or more components. Accordingly, other implementations are within the scope of the claims.

1. A VCSEL array structured light illuminator comprising:
an array of VCSELs operable to produce beams of light;
a projection lens having chief ray angles; and
an optical element disposed between the array of VCSELs and the projection lens, the optical element being operable to bend the beams of light produced by the VCSELs to match corresponding chief ray angles of the projection lens;
wherein the projection lens is operable to project beams of light received from the optical element to generate a structured illumination pattern.

2. The VCSEL array structured light illuminator of claim 1 wherein the optical element comprises a refraction lens.

3. The VCSEL array structured light illuminator of claim 1 wherein the refraction lens is spherical.

4. The VCSEL array structured light illuminator of claim 1 wherein the refraction lens is aspherical.

5. The VCSEL array structured light illuminator of claim 1 wherein the optical element comprises a diffractive optical element.

6. The VCSEL array structured light illuminator of claim 1 wherein the optical element comprises a fresnel lens.

7. The VCSEL array structured light illuminator of claim 1 wherein the optical element comprises a microlens array having layout corresponding to a layout of the VCSEL array with offset array configuration.

8. The VCSEL array structured light illuminator of claim 7 wherein the microlens array is disposed on the VCSEL array.

9. The VCSEL array structured light illuminator of claim 7 wherein the microlens array includes microlenses whose respective positions are offset progressively from corresponding locations of VCSEL array elements.

10. The VCSEL array structured light illuminator of claim 1 wherein the projection lens is a wide-angle projection lens operable to produce a projected image over an angle of 110° or more.

11. An imaging apparatus comprising:
the VCSEL array structured light illuminator of claim 1, wherein the illuminator is operable to project a structured illumination pattern onto one or more objects;
a camera mounted off-axis of the illuminator, the camera being operable to record a structured illumination pattern reflected or scattered by the one or more objects; and
a computing device including one or more processors to compute a respective location or movement of the one or more objects based on the recorded pattern.

12. A method comprising:
producing light beams by an array of light emitting elements;
causing the light beams to be bent by an optical element so as to match corresponding chief ray angles of a projection lens; and
subsequently passing the light beams through the projection lens so as to project a structured illumination pattern onto one or more objects.

13. The method of claim 12 wherein the light beams are produced by an array of VCSELs.

14. The method of claim 12 wherein the light beams from the light emitting elements are bent by at least one of the following so as to match the corresponding chief ray angles of the projection lens: a refractive optical element; a diffractive optical element; a fresnel lens; or a microlens array.

15. The method of claim 12 further including:
recording a structured illumination pattern reflected or scattered by the one or more objects; and
analyzing the recorded pattern using a computing device to determine a respective location and/or movement of the one or more objects.
